(19) United States
(12) Patent Application Publication
(10) Pub. No.: US 2024/0136955 A1
(43) Pub. Date: Apr. 25, 2024

(54) THERMOELECTRIC CLEAN ENERGY

(71) Applicant: James L. Herzog, Edmonds, WA (US)

(72) Inventor: James L. Herzog, Edmonds, WA (US)

(21) Appl. No.: 18/381,026

(22) Filed: Oct. 16, 2023

Related U.S. Application Data
(60) Provisional application No. 63/417,587, filed on Oct. 19, 2022.

(51) Int. Cl. H02N 11/00; H10N 19/00

(52) U.S. Cl. CPC H02N 11/002; H10N 19/00

(57) ABSTRACT

An energy facility with a tank defining a reservoir. A fluid fills the reservoir, a thermoelectric generator is connected to the tank, and a heating element is connected to the tank.

### CROSS-REFERENCE TO RELATED APPLICATIONS

This application claims the benefit of U.S. Provisional Patent Application Ser. No. 63/417,587, filed on Oct. 19, 2022, entitled “THERMOELECTRIC CLEAN ENERGY”, which is hereby incorporated by reference in its entirety for all that is taught and disclosed therein.

### FIELD OF THE INVENTION

The present invention relates to thermoelectric energy.

### BACKGROUND AND SUMMARY

There are problems with energy generation and conservation.

The above disadvantage is addressed by providing an energy facility with a tank defining a reservoir. A fluid fills the reservoir, a thermoelectric generator is connected to the tank, and a heating element connected to the tank.

### BRIEF DESCRIPTION OF THE DRAWINGS

100 is a tank or vessel used for holding and heating a Thermal Transfer Fluid (TTF) or water to a specified temperature with electricity, a battery, solar or a fuel. 101 is an electrical heating element used to heat the fluid. 102 is a fitting thru which cold fluid is flows. 103 is a pump which pumps the fluid to 104 a fluid distribution block where it is directed to 106 a cooling fluid block with multiple Thermoelectric generators (TEG's) 105 attached between 100 and 106 in designated areas with high heat transfer materials. Heat is transferred thru the high heat transfer material into 105 then into 106 where the cold fluid removes the heat and is returned to 107 a return fluid distribution block then to 108 a fitting directing the fluid to 109 a coil which is made of a heat transfer material which runs thru 110 a container made of a plastic or metal such as used in picnic coolers, which also contains a TEC system 111 which is used to cool the fluid being pumped thru the coils or into 110. An electrical distribution box 112 is shown in a different section of 110. TEC 111 is used to chill the air or fluid in 110. 111 has a pump which pumps the heated fluid from the system out to 108 where it flows thru 109 to fitting 102 back to 111. 112 is an electrical distribution box which is used to take in all electrical from the tegs and distribute thru 112 to electrical items such as the pumps 103 and 113 which is a hot fluid recirculation pump used to circulate the hot fluid thru a pipe to 114 and any other electrical uses. 115 is a hole with a cap at the top of the tank used to fill it. 116 is a pressure relief valve used in conjunction with 117 a pipe used to discharge over pressure to a safer area.

FIG. 1 is a view of the container/vessel or tank used for holding heated fluids, water or TTF's (thermal transfer fluid).

FIG. 2 is a view of the water cooling block/liquid cooling block made of heat conducting material to attach the thermal electric generators (TEG's) too, attached to predesignated areas on #1 for heat transfer to TEG's to be cooled by water or TTF's, may also use fan or air to remove heat from cold side of TEG's. These are used to help create a larger temperature difference between the hot and cold sides of the TEG's. After TEG's are attached to the cooling blocks, the blocks will need to be fastened to designated areas on the Tank or vessel (for optimal heat transfer).

FIG. 3 is a view of the multiple TEG's (with various output ratings, Amps, Volts, Watts) cold side to be attached to bottom of water blocks with hot side facing down towards tank or vessel (heated side).

FIG. 4 is a view of the bung and heating element 12, 24, 48 V. Used to heat fluid up too temperature may vary depending on application, hot water tank will have lower temps up to 145 degrees and use low temp TEG's (=to or less than 250c) if current tank not used for hot water, then temp should be 200 degrees Fahrenheit or less. Unless using higher rated TEG's

FIG. 5 is a side view. 105 are Thermoelectric generators which absorb heat from 120 and expel it thru either 106 or 118, 106 is a fluid cooling block and 118 is a heat sink which uses ambient air or forced air to remove heat from.

FIG. 6 is a view of a different variation of the system using an electrical water heater as the source of the heat. 131 a heating element or elements that are used by an electrical source to initially heat the water in the tank to a predetermined temperature. 101 are other heating elements that take over the heating when there is enough electricity to power the system, these elements then heat the water to a higher temperature for better electrical output and maintain that temperature. If all the hot water in the tank is used, then the original source may start up again and help with heating the water, on an as needed basis (used as a backup system). 126 is a hose or pipe connected to the cold-water inlet pipe 127 before entering the tank, this is used to circulate colder water thru 106 the cooling blocks which are attached to an inner tank were the water is heated, the cooling water then flows into the heating tank thru another connection to 127. As the hot water is used, this water then flows into the water heater to replenish the used water from the tank (this water having been warmed requires less energy to heat to temperature). 127 is a cold-water pipe entering the tank. 128 is the hot water pipe leaving the tank. 103 is a circulation pump attached to 126.

FIG. 7 is a view of a different variation of the system using a fuel as the source of the heat and electric heating elements to maintain the temperature of the water. 101 are heating elements. 103 is a circulation pump attached to 126. 126 is a hose or pipe connected to the cold-water inlet pipe 127 before entering the tank, this is used to circulate colder water thru 106 the cooling blocks which are attached to an inner tank were the water is heated, the cooling water then flows into the heating tank thru another connection to 127. As the hot water is used this water then flows into the water heater to replenish the used water from the tank (this water having been warmed requires less energy to heat to temperature). 127 is a cold-water pipe entering the tank. 128 is the hot water pipe leaving the tank. 103 is a circulation pump attached to 126. 127 is the cold-water inlet pipe. 128 is the pipe for the hot water outlet. 129 is a thermistor to monitor the temperature of the water to turn on or off the heating elements, or the fuel as needed 101. 130 is the base with cutouts in it for air circulation for the fuel burner.

FIG. 8 is a view of the pressure relief valve and drainpipe, to help eliminate overpressures.

FIG. 9 is a view of the Mounts for connection to Wall for support.

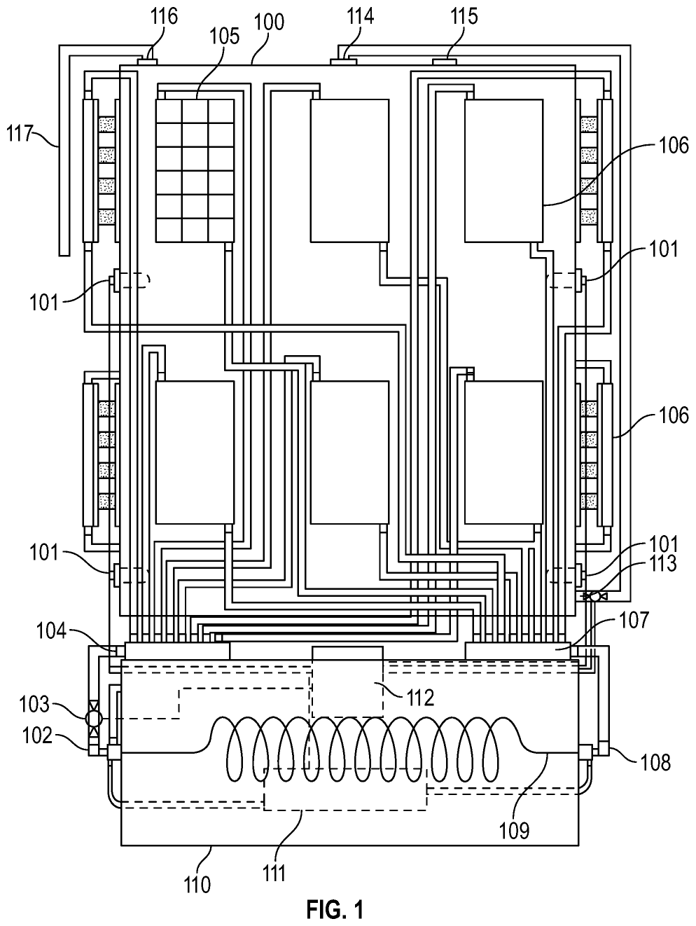

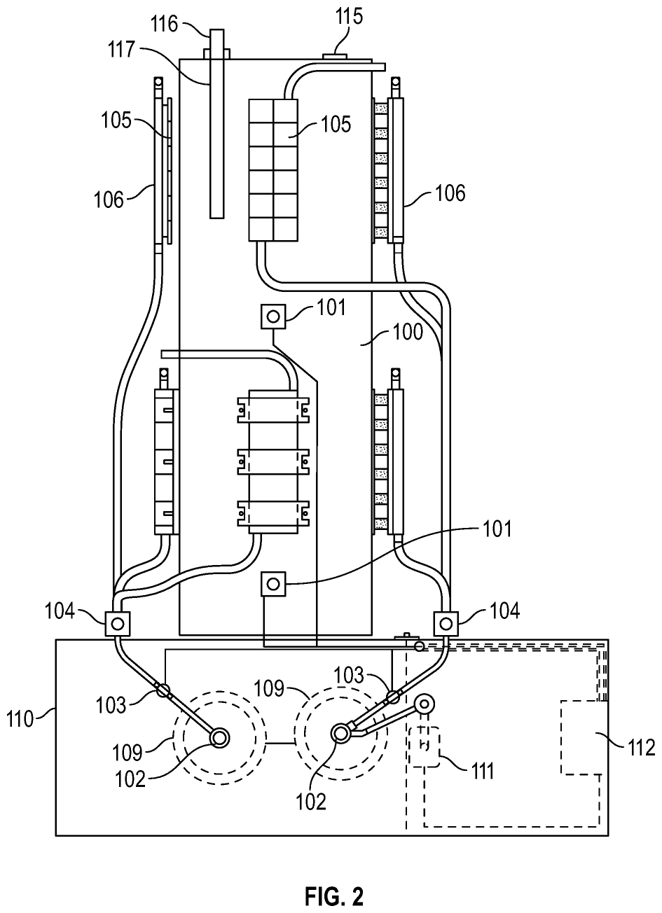

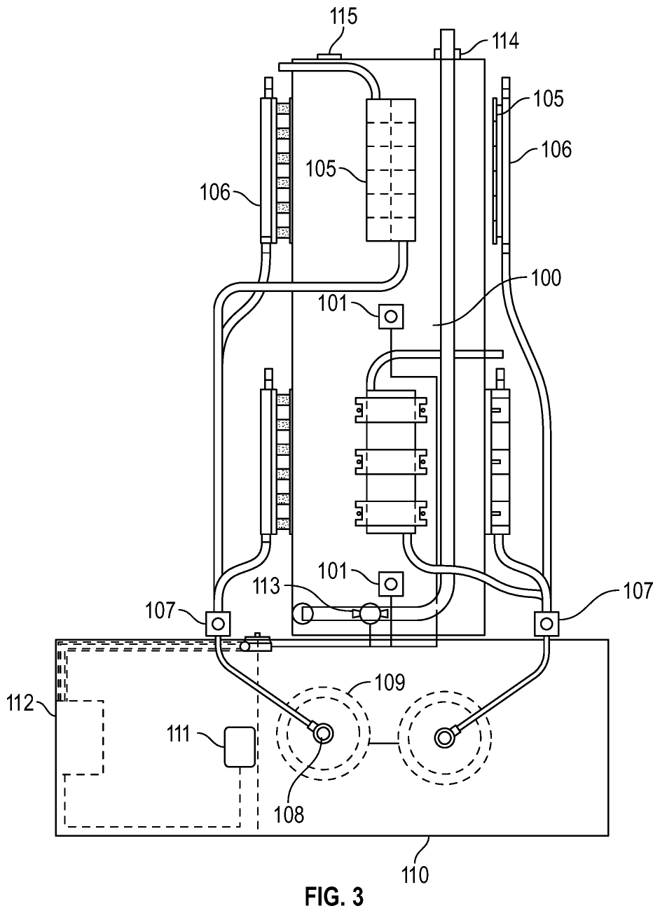

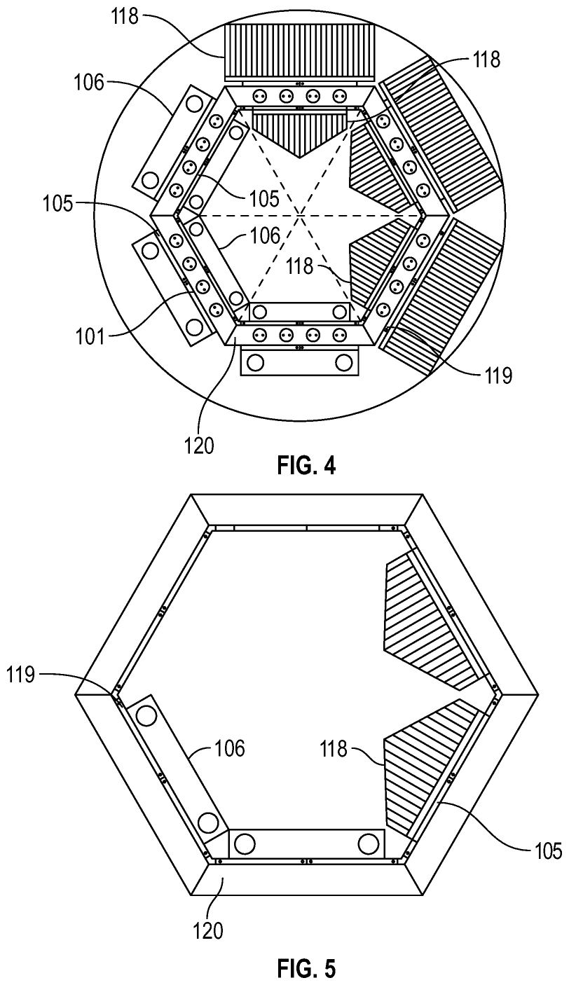

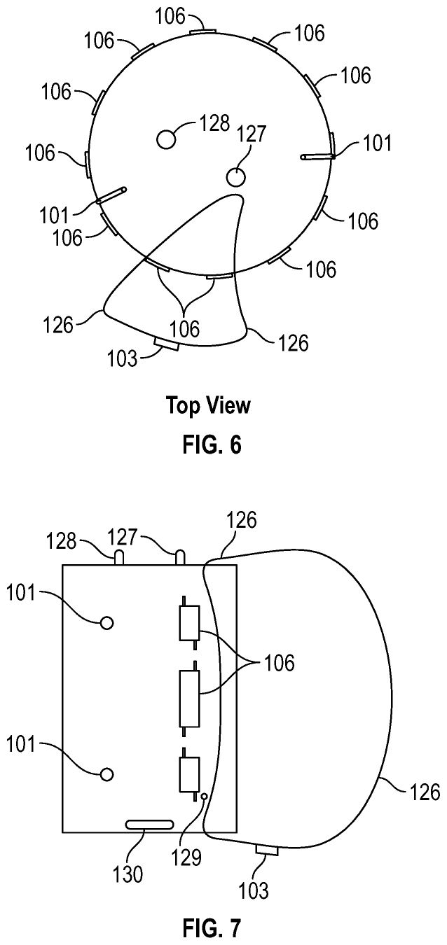

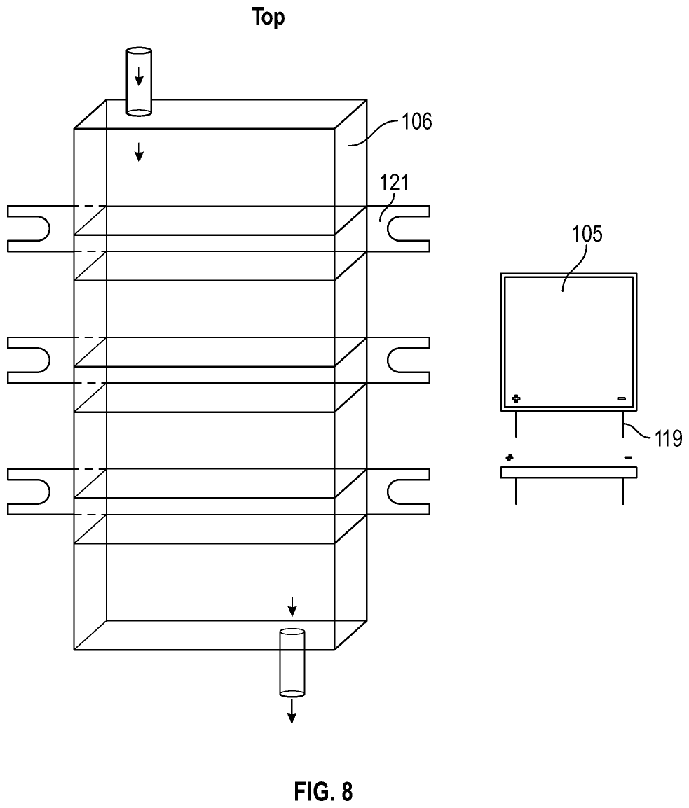

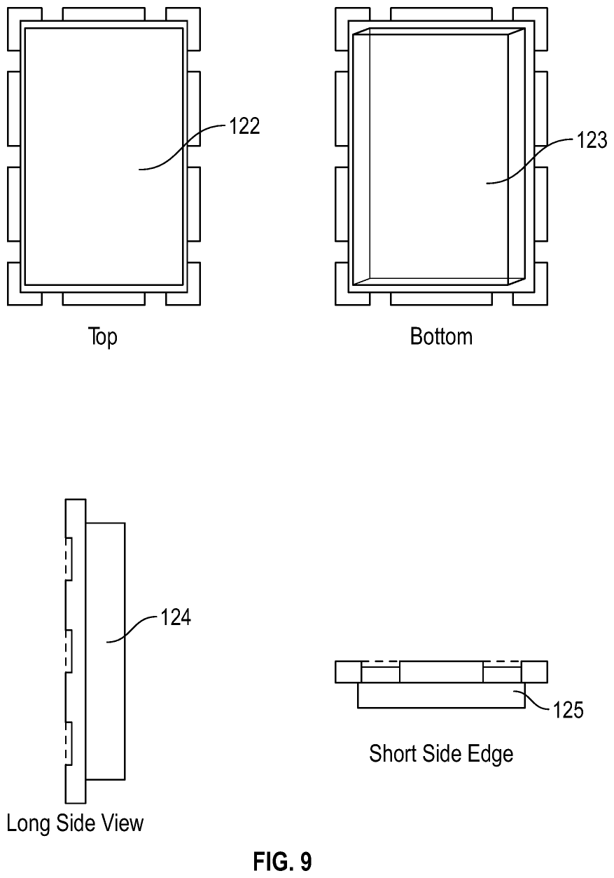

### DETAILED DESCRIPTION OF A PREFERRED EMBODIMENT

The design produces electricity. Using the heat produced from electrical heating elements in a material in some cases by a fuel instead of electric heating elements to heat a fluid. Materials and or fluid initially heated, will then be kept at temperature by the electricity produced by the multiple Thermal electric devices (TEGs) or Thermal electric coolers (TECs) that are attached, using one or more electric heating elements. The system maintains the heat it uses by running electric heating elements and may be used to charge a battery, battery backup system or supplement electricity to other systems that may require power or if attached to the power grid returned as excess in the case of a water heater to keep the water hot for its use.

The system uses heat generated by heating elements, the heat is transferred to a fluid or material such as metal or ceramic to which TEGs or TECs are attached to. They absorb the heat and pass it through two dissimilar metals to the opposite side of the TEG or TEC which creates a voltage. As the source cools the heating elements use some of the power generated to maintain the temperature.

The voltage occurs because of the different temperatures, one side absorbs the heat, and one side expels the heat by using cool or cold air or fluid. The greater the difference in temperature the greater the amount of power that may be generated by a TEG or TEC. Multiple TEGs or TECs connected in series, parallel or series parallel are used to get to the desired output of watts (volts and amps).

TECs may also be used to generate heat or cold by using an electrical current. If used to generate cold, it may be used to cool fluid or air which is then used to cool the TEGS or TECSs to increase the power output of the system. The side of the modules not attached to the hot side can be cooled by ambient air, forced air of cold fluid.

To get the system running It may use DC current, AC current, solar or a fuel such as propane natural gas or wood, once the system is at a temperature to create enough power by the TEGs or TECs they take on the primary duty of heating the material or fluid to a set temperature.

The normal heating system will shut off at a lower temp and kick back on when needed or required, an example of this would be over taxation of a hot water tank by occupants of a building or needs of the hot water for other uses.

A dry system such as one used in a generator setup would use a metal material or a ceramic material to hold the heat. This material would use a heating element or elements to heat it to a desired temperature transferring the heat through it to the tegs or tecs which are attached to the material. The heat will transfer through them to the cold side and produce an electrical current. This electricity will vary depending on the number and electrical output of the tegs or tecs and the size of the system. Some power from the system would be required to continue to power the heating elements and any other electrical devices used.

Heat removed from the TEGs or TECs may be diverted as a supplement to a heating system or diverted somewhere else. A winter summer mode.

Some items that may be required are fluid pumps for hot and cold applications, fans, electrical wire, a battery, or a source to jump start the system and a charge controller or other devices as needed. Inverters would be used to convert the DC current to a usable AC current, such as in a solar system. The size of the system would be determined by its use.

1. An energy facility comprising:
A tank defining a reservoir;
a fluid filling the reservoir;
a thermoelectric generator connected to the tank; and a heating element connected to the tank.
